(19) United States
(12) Patent Application Publication
(10) Pub. No.: US 2018/0321342 A1
(43) Pub. Date: Nov. 8, 2018

(54) ELECTROMAGNET CURRENT CONSTRAINTS

(71) Applicant: Synaptive Medical (Barbados) Inc., Bridgetown (BB)

(72) Inventors: Geron André Bindseil, Toronto (CA); William Bradfield Handler, Toronto (CA)

(21) Appl. No.: 15/774,052

(22) PCT Filed: Nov. 6, 2015
(86) PCT No.: PCT/IB2015/058595

§ 371 Date: May 7, 2018

(51) Int. Cl. G01R 33/385; G01R 33/421

(52) U.S. Cl. CPC G01R 33/385; G01R 33/421

(57) ABSTRACT

In some implementations, a system includes: a housing having a bore in which a subject to be imaged is placed; a main magnet accommodated by the housing and configured to generate a substantially uniform magnetic field within the bore; an N electromagnet comprising a conductive member that includes a first set of one or more non-conductive paths that define at least one conductive channel and a second set of one or more non-conductive paths that, when an electric current is applied to the electromagnet, constrain the electric current along a defined portion of the at least one conductive channel; and a power amplifier configured to apply an electric current to the electromagnet.

### BACKGROUND

The present disclosure relates to magnetic resonance imaging.

### SUMMARY

In one aspect, some implementations provide a system that includes: a housing having a bore in which a subject to be imaged is placed; a main magnet accommodated by the housing and configured to generate a substantially uniform magnetic field within the bore; an electromagnet including a conductive member that includes a first set of one or more non-conductive paths that define at least one conductive channel and a second set of one or more non-conductive paths that, when an electric current is applied to the electromagnet, constrain the electric current along a defined portion of the at least one conductive channel; and a power amplifier configured to apply an electric current to the electromagnet.

Implementations may include one or more of the following features. For example, the system may further include the second set of non-conductive paths are included in a location on the conductive member corresponding to the center of a gradient coil pattern of the electromagnet.

The system may further include the second set of non-conductive paths are included in a location on the conductive member corresponding to the edges of a gradient coil pattern of the electromagnet.

The system may further include conductive member is a metal sheet.

The system may further include the first set of non-conductive paths are recesses in the conductive member from which conductive material has been removed.

The system may further include the second set of non-conductive paths are recesses in the conductive member from which conductive material has been removed.

The system may further include the second set of non-conductive paths are transverse to the first set of non-conductive paths.

The system may further include the second set of non-conductive paths are substantially perpendicular to the first set of non-conductive paths.

The system may further include the defined portion of the at least one conductive channel is a portion of the conductive channel through which the electric current was assumed to flow when the electromagnet was designed.

The system may further include the defined portion of the at least one conductive channel is a center portion of the conductive channel.

The system may further include at least one electrical connector connected in a series circuit with the electromagnet, the electrical connector including at least one conductive channel and a set of one or more non-conductive paths that, when an electric current is applied to the electromagnet, constrain electric current through the electrical connector along a defined portion of the at least one conductive channel of the electrical connector.

In another aspect, some implementations provide a computer-implemented method that includes: forming an electromagnet, where forming the electromagnet includes: forming, in a conductive member, a first set of one or more non-conductive paths that define at least one conductive channel; determining a portion of the at least one conductive channel to which electric current is to be constrained when electric current is applied to the at least one conductive channel; forming, in the conductor, a second set of one or more non-conductive paths that constrain the electric current along the determined portion of the at least one conductive channel when electric current is applied to the at least one conductive channel; coupling the electromagnet to a power amplifier configured to apply an electric current to the electromagnet; and assembling the electromagnet and power amplifier with a housing having a bore in which a subject to be imaged is placed and a main magnet accommodated by the housing and configured to generate a substantially uniform magnetic field within the bore.

In some implementations, forming, in the conductor, a second set of one or more non-conductive paths includes forming one or more constraint cuts in a location on the conductive member corresponding to the center of the gradient coil pattern of the electromagnet.

In some implementations, forming, in the conductor, a second set of one or more non-conductive paths includes forming one or more constraint cuts included in a conductive member on the electromagnet corresponding to the center of a gradient coil pattern of the electromagnet.

In some implementations, forming, in the conductor, the first set of one or more non-conductive paths includes forming recesses in the conductive member by removing conductive material.

In some implementations, forming, in the conductor, the second set of one or more non-conductive paths includes forming recesses in the conductive member by removing conductive material.

In some implementations, forming, in the conductor, the second set of one or more non-conductive paths includes filling the recesses in the conductive member with electrical insulation material.

In some implementations, forming, in the conductor, the second set of one or more non-conductive paths includes forming the second set of non-conductive paths transverse to the first set of non-conductive paths.

In some implementations, forming, in the conductor, the second set of one or more non-conductive paths includes forming the second set of non-conductive paths perpendicular to the first set of non-conductive paths.

In some implementations, the portion of the at least one conductive channel to which electric current is to be constrained is a portion of the conductive channel through which the electric current was assumed to flow when the electromagnet was designed.

### BRIEF DESCRIPTION OF THE DRAWINGS

FIG. 1A-1B illustrate an example of a magnetic resonance imaging (MRI) system with electromagnetic current constraints.

FIG. 2A-2B illustrate examples of conductive materials that include constraint cuts with conducting pathways.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

According to selected embodiments of the present disclosure, magnetic resonance imaging (MRI) systems and devices are provided in which an electromagnet of the MRI system is formed from a conductive member (e.g., a conductive metal sheet) and used to produce a desired magnetic field for imaging. In some instances, a conductive sheet includes one or more non-conductive paths in a particular pattern that defines one or more conductive channels. The pattern of the conductive channels is designed so that a particular magnetic field pattern is produced when current is applied to the one or more conductive channels. The conductive sheet includes additional non-conductive paths that constrain the current to a defined portion of the one or more conductive channels.

For example, gradient coils in an MRI system may be formed from electromagnet windings in a specific pattern to produce a desired magnetic field when energized with electrical current. The current path can be specified by using a solid sheet of conducting material and forming a non-conductive pattern (e.g., by cutting into the sheet) that results in conductive channels between the lines (e.g., cuts) of the non-conductive pattern. This technique has the advantage of using more of the available space for conducting material, which can reduce the overall resistance of the coil and thus also reduce power dissipation. The technique also enables the construction of designs where the adjacent spacing of current can be very small compared to the conductor thickness (e.g. 3 mm spacing using 5 mm thick conductor).

In addition to the non-conductive pattern that forms the conductive channels, one or more additional non-conductive paths (e.g., cuts) are formed on the sheet to constrain the current to a defined portion of the conductive channel. Gradient coil designs may have areas where adjacent current paths have a large separation. For example, in some cases, there may be regions where adjacent current paths are as small as 3 mm apart and other regions where the adjacent current spacing is as large as 50 mm apart. In cases, the adjacent current paths may be smaller than 3 mm apart, and the adjacent current spacing may be larger than 50 mm apart. This means that some of the conductive channels are relatively wide. Having a large conductive channel may result in relatively low resistance and a relatively large area and thermal mass for heat dissipation. However, designs with relatively wide conductive channels but without the additional non-conductive paths may experience several issues.

For instance, the gradient coil may have been designed with the assumption that the current follows the middle, or center, of each conductive channel, but the current may experience Lorentz forces that push its path to one side or another side of the channel depending on the ambient magnetic field. If the current does not follow the design path, the coil's performance may suffer due to worse force and torque balancing, worse shielding, and/or incorrect spatial field variation. In addition, if the area of the conductive channel is large enough, eddy currents can be induced which can affect imaging performance. Including the additional non-conductive paths to constrain the current along the electromagnetic design path (e.g., the center of the conductive channel) may alleviate the issues posed by Lorentz forces and eddy currents.

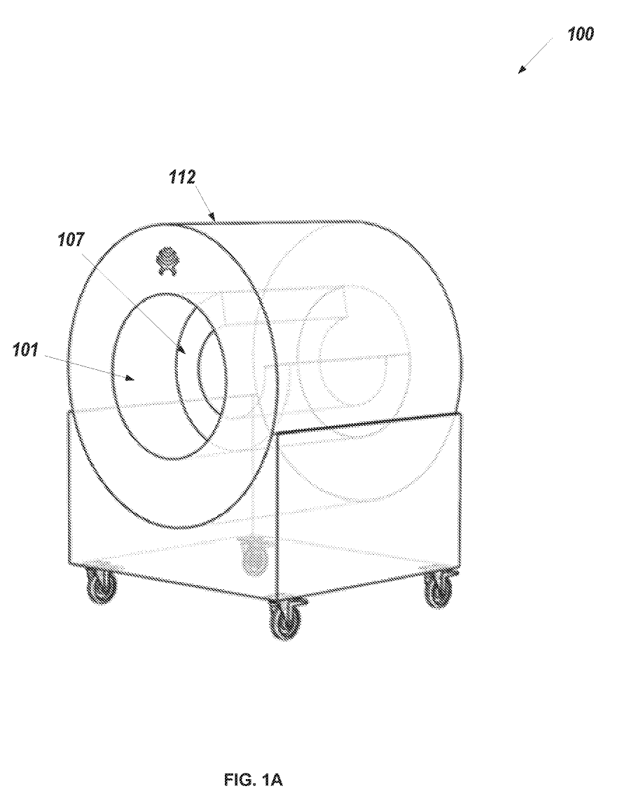

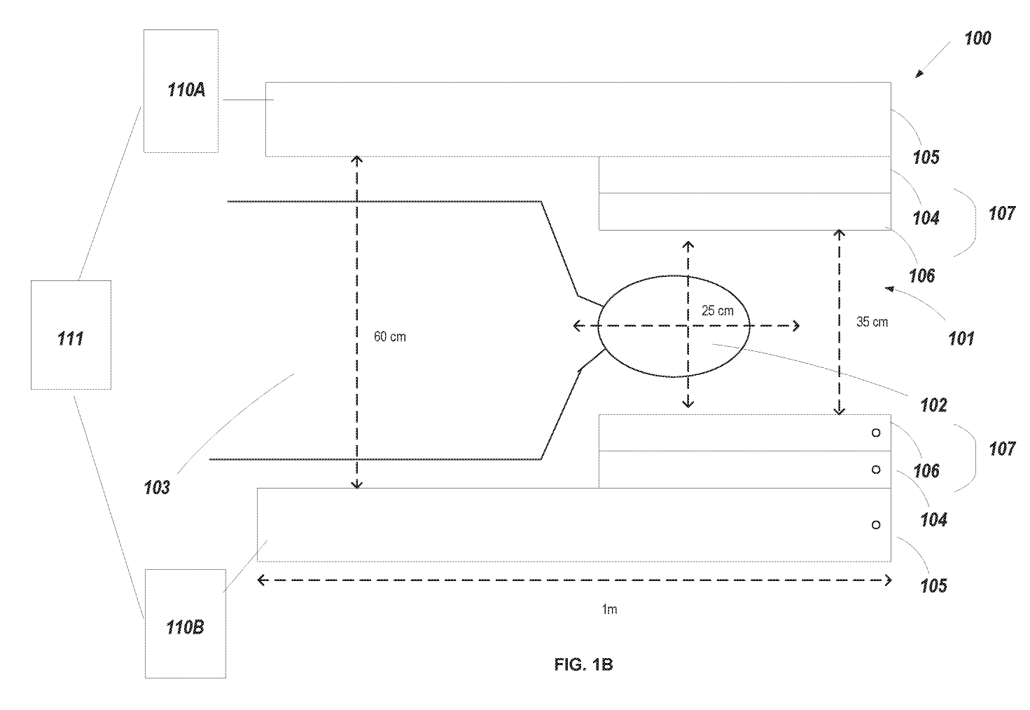

FIGS. 1A-1B show a perspective view and a cross-sectional view of an example of a magnetic resonance imaging (MRI) system 100. The MRI system 100 includes a housing 112 that defines a bore in which a subject to be imaged may be placed during an imaging procedure. The housing 112 accommodates a solenoid magnet 105 that is provided in a cylindrical shape (and therefore likewise defines bore 101). The solenoid magnet 105 may be generally known as the main magnet. The solenoid magnet may generate a substantially uniform magnetic field for imaging a human subject 103 placed inside the bore area 101. The magnetic field that is generated may generally serve as a static polarizing field.

The MRI system 100 includes a coil assembly 107. The coil assembly 107 may generally be shaped as an annular structure and housed within the bore 101. The coil assembly 104 may include a gradient coil 104 and a radio frequency (RF) coil 106. The gradient coil 104 of the coil assembly 107 may generate a perturbation of the static polarizing field to encode magnetizations within the body of the human subject 103. In some implementations, the RF coil 106 of the coil assembly 107 may be used to transmit RF pulses as excitation pulses. The RF coil 106 may also be configured to receive MR signals from the human subject 103 in response to the RF pulses. In some instances, the MRI system 100 may include separate receiving coils to receive the MR signals from the human subject 103. In these instances, the RF signals are, for example, received by local coils for imagining a patient. In one example, a head coil in a birdcage configuration is used for receiving RF signals for imaging the head of the patient head area 102. In another instance, the RF coil may be used for transmitting an RF signal into the subject and a phased array coil configuration may be used for receiving MR signals in response. In some cases, the coil assembly 107 may only include a gradient coil 104, with separate coils being used to transmit and receive the RF signals.

In some implementations, the gradient coil 104 is coupled to and powered by one or more power amplifiers. For example, power amplifiers 110A and 110B, housed in a control room may be connected to gradient coil 104 to drive the gradient coil 104 with current. In driving gradient coil 104, power amplifiers 110A and 110B may be controlled by control unit 111. Control unit 111 generally includes one or more processors as well as programming logic to configure the power amplifiers 110A and 110B. In some instances, control unit 111 is housed in a control room separate from the solenoid magnet 105 of the MRI system 100. In some cases, power amplifiers 110A and 110B may be used to drive the RF coil 106.

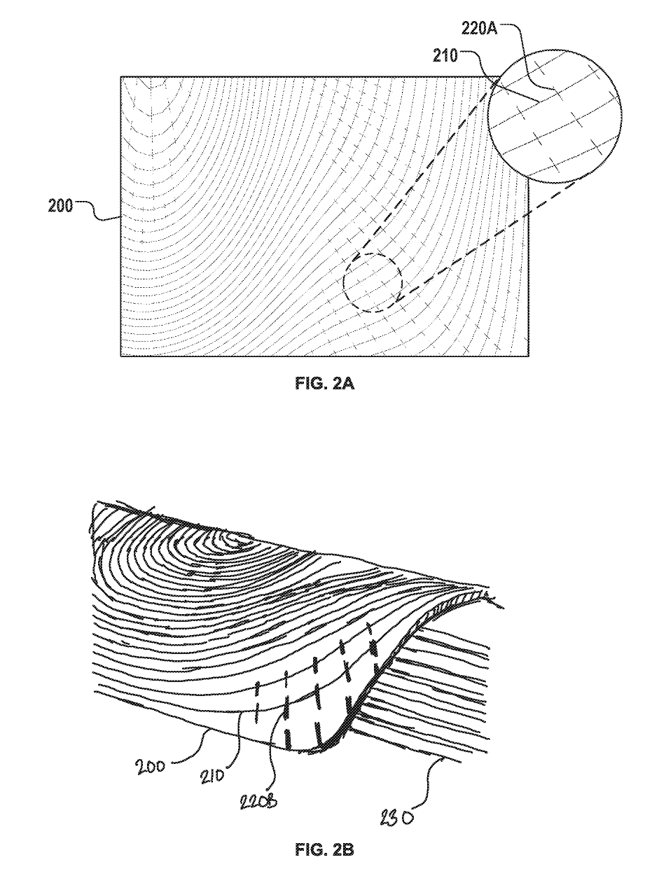

FIGS. 2A-2B illustrate examples of conductive sheets that include non-conductive paths that define conductive channels and non-conductive paths that constrain current to defined portions of the conductive channels. Briefly, FIG. 2A illustrates an example of a conductive sheet 200A that includes current constraints near the center of the conductive sheet 200A. FIG. 2B illustrates an example of a conductive sheet 200B that includes current constraints near the edge of the conductive sheet 200B.

In more detail, FIG. 2A represents a top view of the conductive sheet 200A, which includes one or more non-conductive paths 210 that define conductive channels (for example, channel 212). The conductive sheet 200A also includes a set of non-conductive paths 220A that constrain the flow of current along defined portions of the conductive channels defined by the non-conductive paths 210.

Once the non-conductive paths 210 and 220A are formed, the conductive sheet 200A is used, e.g., as gradient coil 104. Since some of the conductive channels are relatively wide, the gradient coil 104 has a relatively low resistance and a relatively large area and thermal mass for heat dissipation. Since the non-conductive paths 220A constrain the current from flowing along the edge of the conductive channels at the locations of the non-conductive paths 220A, issues related to Lorentz forces and eddy currents in those locations may be reduced or eliminated.

In some implementations, the non-conductive paths 210 may be recesses formed in the conductive sheet 200A by removing conductive material. For example, the non-conductive paths 210 may be cut into the conductive sheet 200 in a particular pattern to form one or more conductive channels. For example, as current flows through the conductive sheet 200A, the non-conductive paths 210 define the boundaries of the current pathways on the conductive sheet 200A where current may flow through. In such instances, the particular pattern used to cut the non-conductive paths 210 may be determined based on the electromagnetic design of the gradient coil or other aspect of an MRI system.

Likewise, the non-conductive paths 220A, or constraint paths, also may be recesses formed in the conductive sheet 200A, for example, by removing conductive material. For example, as described above, the constraint cuts 220A may be cut into the conductive sheet 200A in a particular pattern near to or connected to the non-conductive paths 210 break up the wider conductive channels so that current is forced to flow along a path that follows the electromagnetic design. The cuts may be such that most of the metal is still present for heat dissipation but do not easily allow current to flow at the edges of the conductive channel.

In some instances, the recesses formed in the conductive sheet 200A may be filled with electrical insulation material to rigidly hold adjacent conductive channels together. For example, the insulation material inserted into the recesses may include epoxy that provides electrical insulation between the adjacent conductive channels.

In some instances, as shown in FIG. 2A, the constraint cuts 220A may be formed transverse to the non-conductive paths 210. For example, the constraint cuts 220A may be placed substantially perpendicular to the non-conductive paths 210 such that the length of the constraint cuts 220A required to constrain the current flow through the conducting channels is smaller compared to instances where the constraint cuts 220A are placed at particular angles against the current flow. However, in some cases, the constraint cuts 220A may not be perpendicular to the non-conductive paths 210, but instead are placed at some other angle to the paths 210. For example, non-perpendicular cuts may be used because such cuts may be easier at times to draw in modeling software or due to thermal or mechanical considerations.

The length of the constraint cuts 220A may be adjusted based on the dimensions of the conductive channels and the pattern of the non-conductive paths 210. In some instances, the lengths of the constraint cuts 220A may be larger when placed in wider conducting channels. In other instances, the length of particular constraint cuts 220A within the conductive channel may be based on the particular pattern of the non-conductive paths 210, which adjust the shape of the current pathways along the conductive material 200A. For example, as shown in FIG. 2A, as the width of each conductive channel adjusts from the center to the edges of the conducting member 200A, the lengths of the constraints 220A in each respective conductive channel may also adjust accordingly so as to constrain approximately the same conductive channel width 212.

In some implementations, the conductive sheet 200A may be attached to one or more electrical connectors that are connected in a series circuit with the components of the coil assembly 107 of the MRI system. The electrical connectors ensure that the current that flows through the conductive material 200A flow in the appropriate direction to produce the intended magnetic field for MRI imaging. For instance, current may flow from through the conductive sheet 200A in a particular direction and continue in the same direction when flowing through the electrical conductors.

In some instances, the electrical connectors may additionally include constraint cuts to control the current flow through the electrical connectors. For instance, constraint cuts may be included to allow for the same thermal dissipation performance relative to electrical connectors with larger dimensions. For example, constraint cuts may be included in a particular electrical connector with a large width and a small thickness to constrain the current flow through the center of the electrical connectors while creating a wider area for thermal dissipation. In such examples, the thermal dissipation performance of the particular electrical connector may be comparable to other electrical conductors with a short width and a large thickness.

As shown in FIG. 2A, in some implementations, a set of constraint cuts 220A may be included in a location on the conductive sheet 200A corresponding to the center of a gradient coil pattern of the conducting sheet 200A with the widest conducting paths. The constraint cuts 220A may be used to address problems that are caused by current flow through wide conducting channels. For example, in some instances, current flowing through the wide conducting channels may experience Lorentz forces that push its path to one side or another side of the conducting channel based on the ambient magnetic field. In such instances, the constraint cuts 220A may be placed on the side of the non-conductive paths 210 that is farther from the desired current flow path. In such instances, the non-conductive path 210 on one side of the conducting channel may be close to the desired current flow path and the non-conductive path 210 on the opposite side of the conducting channel 212 may be farther from the desired current path and the farther non-conductive path may then also have constraint cuts 220A. In other instances, the set of constraint cuts 220A may be placed on both sides of the wider conducting channels to mitigate the generation of eddy currents resulting from current flow through the conducting channels.

FIG. 2B illustrates a perspective view of an example of a conductive sheet 200B that includes constraint cuts included in a location on the conductive sheet 200B corresponding to the edges of a gradient coil pattern of the conductive sheet 200B. The constraint cuts 220B prevent current flow at the edges of the conductive channels defined by non-conductive paths 210.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. In one non-limiting example, the terms “about” and “approximately” mean plus or minus 10 percent or less.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A magnetic resonance imaging system comprising:
a housing having a bore in which a subject to be imaged is placed;
a main magnet accommodated by the housing and configured to generate a substantially uniform magnetic field within the bore;
an electromagnet comprising a conductive member that includes a first set of one or more non-conductive paths that define at least one conductive channel and a second set of one or more non-conductive paths that, when an electric current is applied to the electromagnet, constrain the electric current along a defined portion of the at least one conductive channel; and
a power amplifier configured to apply an electric current to the electromagnet.

2. The magnetic resonance imaging system of claim 1, wherein the second set of non-conductive paths are included in a location on the conductive member corresponding to the center of a gradient coil pattern of the electromagnet.

3. The magnetic resonance imaging system of claim 1, wherein the second set of non-conductive paths are included in a location on the conductive member corresponding to the edges of a gradient coil pattern of the electromagnet.

4. The magnetic resonance imaging system of claim 1, wherein the conductive member is a metal sheet.

5. The magnetic resonance imaging system of claim 1, wherein the first set of non-conductive paths are recesses in the conductive member from which conductive material has been removed.

6. The magnetic resonance imaging system of claim 5, wherein the second set of non-conductive paths are recesses in the conductive member from which conductive material has been removed.

7. The magnetic resonance imaging system of claim 1, wherein the second set of non-conductive paths are transverse to the first set of non-conductive paths.

8. The magnetic resonance imaging system of claim 7, wherein the second set of non-conductive paths are substantially perpendicular to the first set of non-conductive paths.

9. The magnetic resonance imaging system of claim 1 wherein the defined portion of the at least one conductive channel is a portion of the conductive channel through which the electric current was assumed to flow when the electromagnet was designed.

10. The magnetic resonance imaging system of claim 1 wherein the defined portion of the at least one conductive channel is a center portion of the conductive channel.

11. The magnetic resonance imaging system of claim 1, comprising at least one electrical connector connected in a series circuit with the electromagnet, the electrical connector including at least one conductive channel and a set of one or more non-conductive paths that, when an electric current is applied to the electromagnet, constrain electric current through the electrical connector along a defined portion of the at least one conductive channel of the electrical connector.

12. A method of forming a magnetic resonance imaging system, the method comprising:
forming an electromagnet, wherein forming the electromagnet includes:
forming, in a conductive member, a first set of one or more non-conductive paths that define at least one conductive channel;
determining a portion of the at least one conductive channel to which electric current is to be constrained when electric current is applied to the at least one conductive channel;
forming, in the conductor, a second set of one or more non-conductive paths that constrain the electric current along the determined portion of the at least one conductive channel when electric current is applied to the at least one conductive channel;
coupling the electromagnet to a power amplifier configured to apply an electric current to the electromagnet;
assembling the electromagnet and power amplifier with a housing having a bore in which a subject to be imaged is placed and a main magnet accommodated by the housing and configured to generate a substantially uniform magnetic field within the bore.

13. The method of claim 12, wherein forming, in the conductor, a second set of one or more non-conductive paths includes forming one or more constraint cuts in a location on the conductive member corresponding to the center of the gradient coil pattern of the electromagnet.

14. The method of claim 12, wherein forming, in the conductor, a second set of one or more non-conductive paths includes forming one or more constraint cuts included in a conductive member on the electromagnet corresponding to the center of a gradient coil pattern of the electromagnet.

15. The method of claim 12, wherein forming, in the conductor, the first set of one or more non-conductive paths includes forming recesses in the conductive member by removing conductive material.

16. The method of claim 15, wherein forming, in the conductor, the second set of one or more non-conductive paths includes forming recesses in the conductive member by removing conductive material.

17. The method of claim 16, wherein forming, in the conductor, the second set of one or more non-conductive paths includes filling the recesses in the conductive member with electrical insulation material.

18. The method of claim 12, wherein forming, in the conductor, the second set of one or more non-conductive paths includes forming the second set of non-conductive paths transverse to the first set of non-conductive paths.

19. The method of claim 18, wherein forming, in the conductor, the second set of one or more non-conductive paths includes forming the second set of non-conductive paths perpendicular to the first set of non-conductive paths.

20. The method of claim 12 wherein the portion of the at least one conductive channel to which electric current is to be constrained is a portion of the conductive channel through which the electric current was assumed to flow when the electromagnet was designed.
